(19) United States
(12) Patent Application Publication
(10) Pub. No.: US 2024/0379908 A1
(43) Pub. Date: Nov. 14, 2024

(54) SEMICONDUCTOR STRUCTURE AND METHOD OF FORMING THE SAME

(71) Applicant: Lextar Electronics Corporation, Hsinchu City (TW)

(72) Inventors: Guo-Yi SHIU, Hsinchu City (TW); Shiou-Yi KUO, Hsinchu City (TW)

(21) Appl. No.: 18/637,388

(22) Filed: Apr. 16, 2024

(30) Foreign Application Priority Data
May 10, 2023 (TW) 112117260

(51) Int. Cl. H01L 33/38; H01L 33/62

(52) U.S. Cl. CPC H01L 33/382; H01L 33/62; H01L 2933/0016; H01L 2933/0066

(57) ABSTRACT

A semiconductor structure includes a micro semiconductor device and a support fragment. The micro semiconductor device has a first surface and a second surface opposite the first surface. The micro semiconductor device includes a first electrode and a second electrode on the first surface. The first electrode and the second electrode are separated from each other. The support fragment is left on the micro semiconductor device and positioned corresponding to the region between the main portion of the first electrode and the second electrode in the vertical direction. The support fragment has an annular breaking surface in a plan view of the support fragment.

### CROSS REFERENCE TO RELATED APPLICATIONS

This Application is based on, and claims priority of TW application Ser. No. 11/211,7260 filed on May 10, 2023, the content of the entirety of which is incorporated by reference herein.

### BACKGROUND OF THE DISCLOSURE

### Field of the Disclosure

The present disclosure relates to a semiconductor structure and a method of forming the same, and in particular to a semiconductor structure having a support fragment and a method of forming the same.

### Description of the Related Art

With the development of optoelectronic technology, the designers of various types of display devices are constantly improving the characteristics and performance of the devices, such as increasing resolution and reducing size and saving energy, and a display device with micro-light-emitting diodes (μLED) is one of the most important types of the development. The advantages of micro-light-emitting diodes include low power consumption, high brightness, high resolution and high color saturation. Thus, the micro-light-emitting diode display devices are regarded as the mainstream of the next generation of display technology.

The micro-light-emitting diode is configured as a traditional standard light emitting diode with a reduced size to an order of magnitude below about 100 microns or even tens of microns. Since the size of a micro-light-emitting diode is very small, the number of light emitting diodes formed in the same area increases dramatically. After micro-light-emitting diodes are fabricated on a growth substrate, support structures (also called weakened structures) that weaken the connection between the micro-light-emitting diodes and the substrate can be formed. Then, the micro-light-emitting diodes are picked up and transferred to another target substrate in large quantities by using a precise pick-up technology (such as using a transfer stamp with electrostatic force). Currently, the weakened structures between the micro-light-emitting diodes and the substrate can be divided into tether-type weakened structures and anchor-type weakened structures. The tether-type weakened structures occupy additional areas of the substrate, thereby affecting the number of micro-light-emitting diodes that can be produced on a single wafer. In addition, the weakened anchor-type structures suffer from poor pick-up during the pick-up step due to the solid support. Thus, although existing micro semiconductor structures and their method have been adequate for their intended purposes, they have not been entirely satisfactory in all respects.

### BRIEF SUMMARY OF THE DISCLOSURE

Some embodiments of the present disclosure provide semiconductor structures. An embodiment of a semiconductor structure includes a micro semiconductor device and a support fragment. The micro semiconductor device has a first surface, a second surface opposite the first surface, first electrode on the first surface, and a second electrode on the first surface. The first electrode and the second electrode are separated from each other, and the first electrode has a main portion. The support fragment connects to the micro semiconductor device and corresponds to a region between the main portion of the first electrode and the second electrode in a vertical direction. The support fragment has an annular breaking surface in a plan view of the micro semiconductor device.

Some embodiments of the present disclosure provide a method of forming a semiconductor structure. The method includes providing a micro semiconductor device having a first surface, a second surface opposite the first surface, a first electrode on the first surface, and a second electrode on the first surface. The first electrode and the second electrode are separated from each other, and the first electrode has a main portion. The method includes forming a support fragment connected to the micro semiconductor device. The support fragment corresponds to a region between the main portion of the first electrode and the second electrode in a vertical direction. The support fragment has an annular breaking surface in a plan view of the micro semiconductor device.

A detailed description is given in the following embodiments with reference to the accompanying drawings.

### BRIEF DESCRIPTION OF THE DRAWINGS

The present disclosure can be more fully understood by reading the subsequent detailed description and examples with references made to the accompanying drawings, wherein:

FIG. 1 is a schematic plan view of a semiconductor device in accordance with some embodiments of the present disclosure.

FIG. 2A-FIG. 2I illustrate cross-sectional views of different stages of a method of forming a semiconductor structure having a support fragment in accordance with some embodiments of the present disclosure.

FIG. 3A is an enlarged view of a semiconductor structure in accordance with some embodiments of the present disclosure.

FIG. 3B is a schematic plan view of FIG. 3A.

FIG. 4A-FIG. 4M illustrate cross-sectional views of different stages of forming another semiconductor structure having a support fragment in accordance with some embodiments of the present disclosure.

### DETAILED DESCRIPTION OF THE DISCLOSURE

In order to make the description of the present disclosure more detailed and complete, the following provides an illustrative description for the implementation aspects and specific embodiments of the present disclosure; but this is not the only form of implementing or using the specific embodiments of the present disclosure. The embodiments disclosed below can be combined or substituted with each other under beneficial circumstances, and other embodiments can also be added to one embodiment without further description or explanation. In addition, it will be understood that although the terms like “first”, “second”, “third” may be used herein to describe various elements, components, regions, layers, and/or portions, these elements, components, regions, layers, and/or portions should not be limited by these terms, and these terms are only used to distinguish between different elements, components, regions, layers, and/or portions. Thus, a first element, component, region, layer, and/or portion discussed below could be referred to as a second element, component, region, layer, and/or portion without departing from the teachings of the present disclosure.

Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, spatially relative terms, such as “beneath”, “below”, “lower”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented and the spatially relative descriptors used herein may likewise be interpreted accordingly. In addition, the present disclosure may repeat reference numbers and/or letters in the various examples. This repetition is for the purpose of simplicity and clarity and does not in itself dictate a relationship between the various embodiments and/or configurations discussed.

In the embodiments, semiconductor structures and methods of forming the same are provided. In some embodiments, a semiconductor structure includes a semiconductor device such as a micro semiconductor device and a support fragment connected to the semiconductor device. The support fragment has an annular breaking surface in a plan view of the support fragment. In addition, the support fragment of the embodiments is disposed within an area of a substrate occupied by the semiconductor device connected to the support fragment without occupying additional lateral space of the substrate, thereby increasing the number of the semiconductor devices that can be fabricated on the substrate. In addition, according to the method of forming a semiconductor structure in some embodiments, a void is formed between the support structure and a connection assembly, so the support structure can be broken off easily.

The present disclosure is described fully hereinafter with reference to the accompanying drawings, in which embodiments of the present disclosure are shown. It should be noted, however, that the present disclosure is not limited to the following embodiments, and may be implemented in various forms. The drawings as illustrated are only schematic and are non-limiting. For example, for clarity, the relative size, thickness, and position of each layer, each area, and/or each structure may be reduced or enlarged. Some embodiments are described below. Throughout the various views and illustrative embodiments, similar reference numbers are used to designate similar features/components.

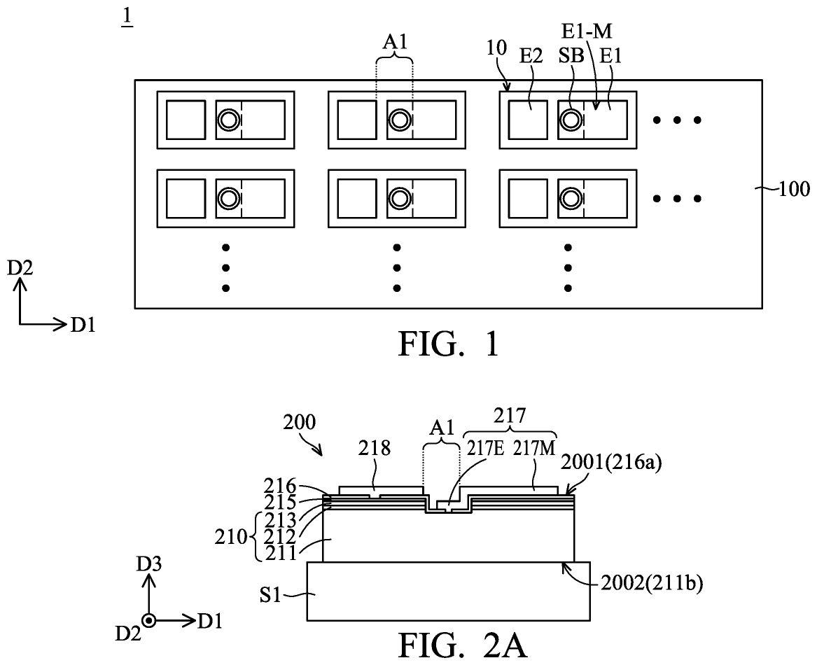

FIG. 1 is a schematic plan view of a semiconductor device in accordance with some embodiments of the present disclosure. The semiconductor device 1 includes several semiconductor structures 10 disposed on a substrate 100. The semiconductor structures 10 may be arranged in an array on the substrate 100. For example, several semiconductor structures 10 are arranged in the first direction D1 and the second direction D2, and any two adjacent semiconductor structures 10 are separated by a distance, but the present disclosure is not limited thereto. Each of the semiconductor structures 10 includes a first electrode E1 and a second electrode E2. The first electrode E1 and the second electrode E2 have different electrical properties. Each of the semiconductor structures 10 further includes a support fragment SB on the first electrode E1 in accordance with some embodiments of the present disclosure. Specifically, the support fragment SB is on a region A1 between the main portion E1-M of the first electrode E1 and the second electrode E2. In addition, the support fragment SB may be in direct contact with the first electrode E1 or not in direct contact with the first electrode E1.

In addition, the semiconductor structure in some embodiments may include a micro semiconductor device, such as a micro-light-emitting diode (micro-LED). For the sake of simplicity and clarity, FIG. 1 only depicts the relative positions of the first electrode E1, the second electrode E2 and the support fragment SB in each of the semiconductor structures 10 for illustration.

Method of forming a semiconductor structure and the formed semiconductor structure with the support fragment SB in accordance with some embodiments of the present disclosure are described below. In addition, additional procedures may be provided before, during, and after the method, and some of the recited steps may be replaced or eliminated for different embodiments of the disclosure.

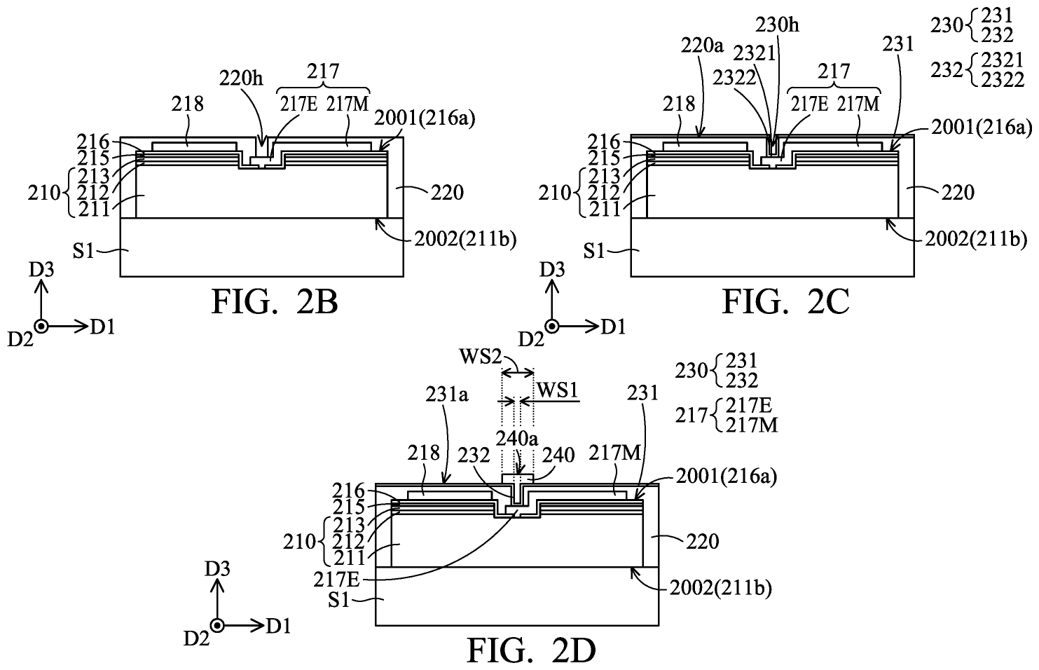

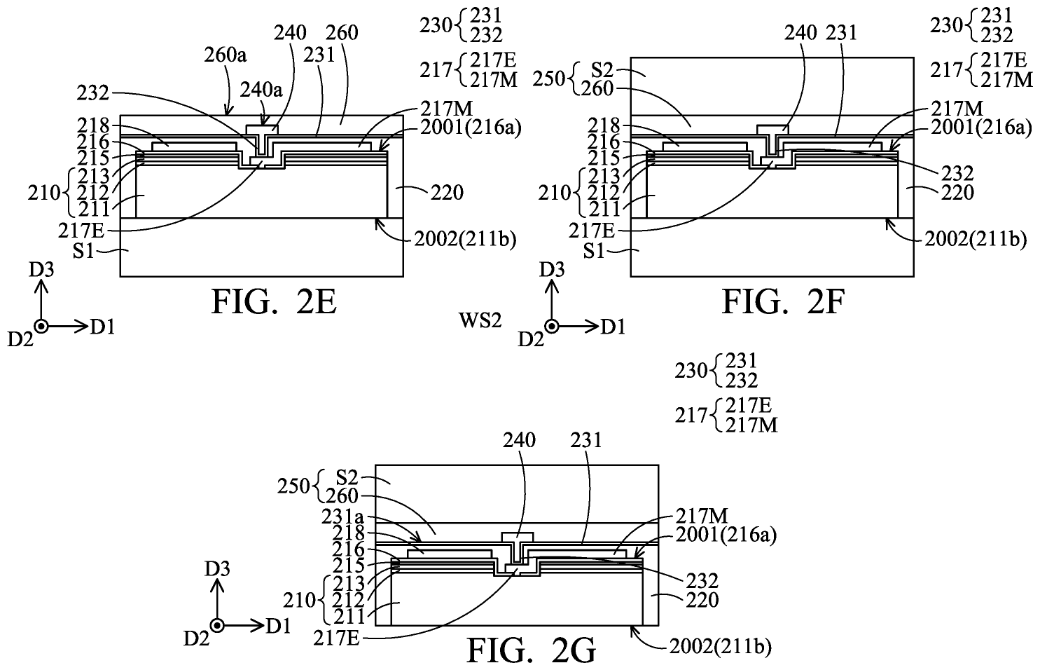

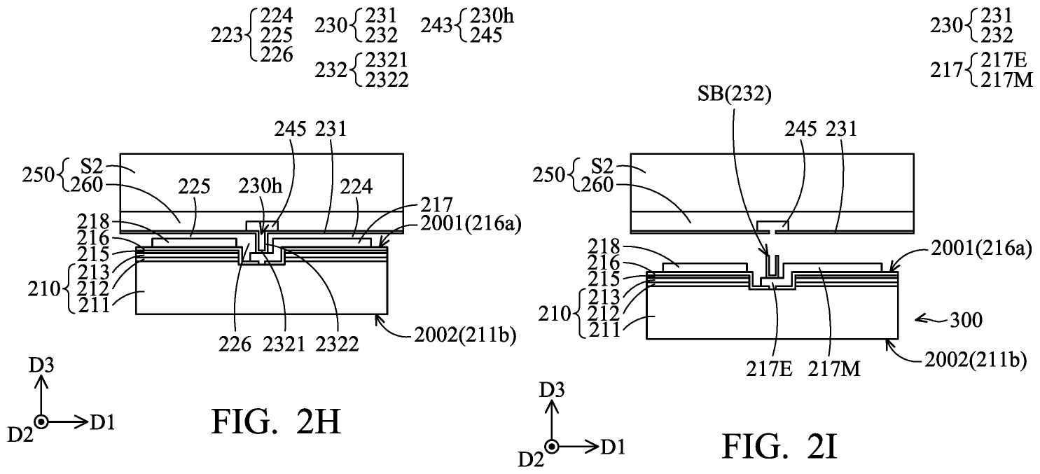

FIG. 2A-FIG. 2I illustrate cross-sectional views of different stages of a method of forming a semiconductor structure having a support fragment in accordance with some embodiments of the present disclosure. For the sake of simplicity and clarity, FIG. 2A-FIG. 2I merely illustrate a method of forming a single semiconductor structure 10.

Referring to FIG. 2A, a micro semiconductor device 200 (such as a micro-light-emitting diode) is formed on the first substrate S1 in accordance with some embodiments of the present disclosure. In some embodiments, the first substrate S1 is a growth substrate, and may include silicon, sapphire, gallium arsenide (GaAs) or other suitable materials. An epitaxial stack 210 is formed on the first substrate S1. The epitaxial stack 210 includes, for example, a first semiconductor layer 211, a light-emitting layer 212 and a second semiconductor layer 213 sequentially stacked on the first substrate S1 from bottom to top (for example, along the third direction D3). The first semiconductor layer 211 and the second semiconductor layer 213 have different conductivity types. In some embodiments, the first semiconductor layer 211 is a semiconductor layer with a first conductivity type, such as an n-type semiconductor layer. The second semiconductor layer 213 is a semiconductor layer with a second conductivity type, such as a p-type semiconductor layer.

In some embodiments, the first semiconductor layer 211 includes one or more group III-V semiconductor materials, such as gallium nitride (GaN), gallium arsenide (GaAs), gallium phosphide (GaP), indium arsenide (InAs), aluminum nitride (AlN), indium nitride (InN), indium phosphide (InP), other binary epitaxial material, or the like. The first semiconductor layer 211 may also include aluminum gallium nitride (AlGaN), aluminum gallium arsenide (AlGaAs), indium gallium phosphide (InGaP), indium gallium nitride (InGaN), aluminum indium gallium nitride (AlInGaN), aluminum indium gallium phosphide (AlInGaP), indium gallium arsenide phosphide (InGaAsP), other ternary or quaternary epitaxial materials, or the like. In addition, in some embodiments, the group III-V semiconductor layer can be doped with group IVA elements (such as silicon) to form an n-type first semiconductor layer 211. In addition, the first semiconductor layer 211 can be a single-layer structure or a multi-layer structure. A single layer of the first semiconductor layer 211 is depicted in the drawings for the sake of simplicity and clarity.

In some embodiments, the light-emitting layer 212 formed on the first semiconductor layer 211 can be referred to as an active layer. When the electric current passes through the active layer, the active layer emits light of a specific color. The light-emitting layer 212 may include multiple quantum wells (MQW), single quantum well (SQW), homojunction, heterojunction, or other similar structure, but the present disclosure is not limited thereto.

In some embodiments, the second semiconductor layer 213 on the light-emitting layer 212 may include the aforementioned binary, ternary or quaternary epitaxial materials of group III-V semiconductors, which is not be repeated here. Moreover, the second semiconductor layer 213 and first semiconductor layer 211 have different conductivity types. In some embodiments, the group III-V semiconductor layer can be doped with group IIA elements (such as beryllium, magnesium, calcium or strontium) to form a p-type second semiconductor layer 213. In one embodiment, the first semiconductor layer 211 includes n-type GaN, and the second semiconductor layer 213 includes p-type GaN. In addition, in some implementations, the width of the second semiconductor layer 213 is substantially equal to the width of the underlying light-emitting layer 212, but the present disclosure is not limited thereto.

In some embodiments, the micro semiconductor device 200 further includes a conductive layer 215 formed on the second semiconductor layer 213, and a passivation layer 216 formed on the conductive layer 215. The conductive layer 215 may include metal oxides, metals, other suitable conductive materials, or the combination thereof. The foregoing metal oxides are, for example, indium tin oxide (ITO), indium zinc oxide (IZO), aluminum zinc oxide (AZO), other suitable metal oxide, or the combination thereof. The foregoing metals are, for example, titanium (Ti), nickel (Ni), aluminum (Al), gold (Au), platinum (Pt), chromium (Cr), silver (Ag), copper (Cu), other suitable metal, the alloy thereof, or the combination thereof. In some other embodiments, the conductive layer 215 may be omitted.

The passivation layer 216 covers the first semiconductor layer 211, the light-emitting layer 212 and the second semiconductor layer 213. In some embodiments, the passivation layer 216 includes an insulating material. In addition to being an insulator, the passivation layer 216 protects and prevents the first semiconductor layer 211, the light-emitting layer 212 and the second semiconductor layer 213 from being damaged by the mechanical strength of the passivation layer 216.

In addition, in this embodiment, the passivation layer 216 has openings to respectively expose a portion of the first semiconductor layer 211 and a portion of the conductive layer 215 on the second semiconductor layer 213. In some embodiments, the passivation layer 216 can be formed by chemical vapor deposition (CVD), printing, coating, or other suitable methods. Besides, the openings that penetrate through the passivation layer 216 may be formed by lithography and etching processes or other suitable processes.

In some other embodiments, a reflective layer (not shown) and a barrier layer (not shown) can be formed on the conductive layer 215. The passivation layer 216 is formed on the barrier layer (not shown). The reflective layer can reflect light, and the barrier layer can protect and fix the reflective layer to prevent the reflective layer from being oxidized and peeled off. The reflective layer may include silver, aluminum, other suitable materials, the alloy thereof, or a combination thereof. The barrier layer may include titanium, platinum, gold, nickel, tungsten, tungsten-titanium alloy, aluminum, silver alloy, other suitable materials, or a combination thereof. In some examples, the reflectivity of the reflective layer is greater than the reflectivity of the barrier layer. In addition, in some examples, the conductive layer 215 (such as transparent indium tin oxide, ITO) disposed between the second semiconductor layer 213 (such as a p-type semiconductor layer) and the reflective layer can improve the uniformity of the current distribution between the second semiconductor layer 213 and the reflective layer.

According to some embodiments, the micro semiconductor device 200 has a first surface 2001 and a second surface 2002 opposite to the first surface 2001. In this embodiment, as shown in FIG. 2A, the top surface 216a of the passivation layer 216 is also referred to as the first surface 2001 of the micro semiconductor device 200, and the bottom surface 211b of the first semiconductor layer 211 is also referred to as the second surface 2002 of the micro semiconductor device 200. In addition, in this embodiment, the second surface 2002 is a light exist surface of the micro-semiconductor device 200.

In some embodiments, the micro semiconductor device 200 further includes a first electrode 217 and a second electrode 218 disposed on the first surface 2001. An electrode material layer can be formed on the first surface 2001 by a suitable process such as a sputtering method or electron beam physical deposition, and the electrode material layer fills the opening of the passivation layer 216. After the electrode material layer is formed, an annealing treatment can be performed to increase the ohmic contact between the electrode material layer and the epitaxial stack 210. Then, the first electrode 217 and the second electrode 218 are formed by performing a patterning process, including an etching process. Therefore, in this embodiment, the first electrode 217 and the second electrode 218 are separated from each other, and the first electrode 217 is electrically connected to the first semiconductor layer 211 through the opening of the passivation layer 216. The second electrode 218 is electrically connected to the conductive layer 215 and the second semiconductor layer 213 through another opening of the passivation layer 216. The first electrode 217 and the second electrode 218 may include other suitable electrode material, such as gold (Au), titanium (Ti), nickel (Ni), aluminum (Al), platinum (Pt), chromium (Cr), silver (Ag), copper (Cu), other suitable conductive materials, the alloy thereof, or a combination of the foregoing material.

In some embodiments, the first electrode 217 includes a main portion 217M and an extension portion 217E. The extension portion 217E is connected to the main portion 217M and extends towards the second electrode 218 into a region A1 between the main portion 217M and the second electrode 218. In addition, the main portion 217M of the first electrode 217 is, for example (but not limited to), disposed on the same level as the second electrode 218. In this embodiment, the opening of the passivation layer 216 that exposes a portion of the first semiconductor layer 211 is located in the region A1, and the extension portion 217E fills up the opening, so that the first electrode 217 is electrically connected the first semiconductor layer 211.

The material and shape of each layer of the above-mentioned micro semiconductor device 200 are only provided for illustrative purposes. Other micro semiconductor device that has different configurations (including different materials and shapes of each layer) can also be applied to the embodiments of the present disclosure and is not limited thereto.

Next, referring to FIG. 2B, in some embodiments, a first sacrificial layer 220 is formed on the micro semiconductor device 200 in FIG. 2A. The first sacrificial layer 220 is formed on the first surface 2001 of the micro semiconductor device 200 and covers the micro semiconductor device 200. As shown in FIG. 2B, the first sacrificial layer 220 also covers the first electrode 217 and the second electrode 218. In addition, the first sacrificial layer 220 has a hole 220h that is positioned between the first electrode 217 and the second electrode 218 correspondingly positioned in the region A1. The hole 220h exposes a portion of the first electrode 217. Specifically, in this embodiment, the hole 220h of the first sacrificial layer 220 exposes a portion of the extension portion 217E of the first electrode 217.

In some embodiments, the first sacrificial layer 220 includes benzocyclobutene (BCB), polyimide (PI), or other suitable sacrificial materials that can be removed easily in subsequent processes. The first sacrificial layer 220 includes one or more sacrificial materials. The first sacrificial layer 220 can be a single-layer structure or a multi-layer structure. In this exemplified embodiment, the first sacrificial layer 220 is depicted as a single-layer structure for the purpose of simplicity and clarity of the drawings.

Next, referring to FIG. 2C, a material layer is conformally deposited on the first sacrificial layer 220 to form a support structure 230, in accordance with some embodiments of the disclosure. The support structure 230 includes a suspension portion 231 and a liner portion 232. The material layer is conformally deposited in the hole 220h of the first sacrificial layer 220 to form the liner portion 232 and define a recess 230h.

Specifically, in some examples, the liner portion 232 includes a bottom portion 2321 and an annular sidewall 2322. The bottom portion 2321 is positioned on the micro semiconductor device 200, for example, disposed on the first electrode 217 and in contact with the extension portion 217E. The annular sidewall 2322 is connected to the bottom portion 2321. In addition, the bottom portion 2321 and the annular sidewall 2322 collectively define the recess 230h.

Specifically, in some embodiments, the suspension portion 231 is connected to the annular sidewall 2322 of the liner portion 232, and the suspension portion 231 extends over the first electrode 217 and the second electrode 218. For example, the suspension portion 231 is integrally formed on the top surface 220a of the first sacrificial layer 220. It should be noted that the suspension portion 231 is not in direct contact with the first electrode 217 and the second electrode 218. As shown in FIG. 2C, the suspension portion 231 is separated from the first electrode 217 and the second electrode 218 in the third direction D3 by the first sacrificial layer 220.

In some embodiments, the support structure 230 includes an insulating material, a metal material, or other suitable supporting materials. The foregoing insulating material includes silicon oxide, silicon nitride, silicon oxynitride, one or more ceramic material, epoxy resin, other suitable materials, or the combination thereof, but the present disclosure is not limited thereto. The foregoing metal material includes aluminum, titanium, gold, platinum or nickel, but the present disclosure is not limited thereto. In addition, the support structure 230 may be a single-layer structure or a multi-layer structure. The support structure 230 is depicted as a single-layer structure in the drawings for the sake of simplicity and clarity. In some embodiments, the thickness of the material layer of the support structure 230 is, for example, in a range of about 0.5 μm to 5 μm.

In addition, in this embodiment, the support structure 230 and the subsequently formed support fragment SB (FIG. 2I) from the support structure 230 are positioned on the first surface 2001 (which is not the light exist surface) of the micro semiconductor device 200. Therefore, the support structure 230 may be formed by using a light transmissive material or an opaque material. However, in some other embodiments where the support fragment is formed on the light exist surface of the micro semiconductor device 200, the support structure 230 is formed by using a material having a high degree of light transmittance (for example, having a light transmittance that is greater than or equal to 80%).

Next, referring to FIG. 2D, a second sacrificial layer 240 is formed at the recess 230h in accordance with some embodiments of the present disclosure. Specifically, the second sacrificial layer 240 is formed on a portion of the support structure 230. As shown in FIG. 2D, the second sacrificial layer 240 is formed in the recess 230h to cover the liner portion 232 of the support structure 230. Moreover, the second sacrificial layer 240 extends from the recess 230h to outside of the recess 230h and covers a portion of the suspension portion 231. In some embodiments, the top surface 240a of the second sacrificial layer 240 is higher than the top surface 231a of the suspension portion 231. In addition, in the first direction D1, the second sacrificial layer 240 has different width. For example, the width WS2 of the portion of the second sacrificial layer 240 that is higher than the support structure 230 is greater than the width of WS1 of the other portion of the second sacrificial layer 240 that fills the recess 230h. It should be noted that the portion of the second sacrificial layer 240 that is lower than the suspension portion 231 of the support structure 230, i.e. the portion of the second sacrificial layer 240 that fills recess 230h, forms a pillar. In some embodiments, the second sacrificial layer 240 can be connected to another second sacrificial layer next to the second sacrificial layer 240 by the aforementioned extension during forming a plurality of the semiconductor structures, thereby facilitating the subsequent removal process.

In some embodiments, the second sacrificial layer 240 includes benzocyclobutene (BCB), polyimide (PI), or other suitable materials. The second sacrificial layer 240 may include one or more materials. The second sacrificial layer 240 and the first sacrificial layer 220 may include different materials or the same material. When the second sacrificial layer 240 and the first sacrificial layer 220 include the same material, they can be removed simultaneously in the same subsequent process.

Next, a connection assembly 250 is formed on the support structure 230 and the second sacrificial layer 240. As shown in FIG. 2E and FIG. 2F, the connection assembly 250 includes, for example, an adhesive layer 260 and a second substrate S2.

Referring to FIG. 2E, the adhesive layer 260 is formed on the support structure 230 and the second sacrificial layer 240 in accordance with some embodiments of the present disclosure. Specifically, the adhesive layer 260 covers the suspension portion 231 and the second sacrificial layer 240. In this embodiment, the top surface 260a of the adhesive layer 260 is higher than the top surface 240a of the second sacrificial layer 240.

In some embodiments, the adhesive layer 260 may include insulating adhesive, conductive adhesive, metal, other suitable material, or a combination thereof. For examples, the insulating adhesive may include epoxy resin, silica gel, other suitable material, or a combination thereof; the conductive adhesive may include epoxy resin mixed with silver powder, other suitable material, or a combination thereof; the metal may include copper, aluminum, tin, silver, other suitable metal, or the combination thereof; but the disclosure is not limited thereto.

In addition, in some embodiments, the adhesive layer 260 may be a single-layer structure or a multi-layer structure, but the disclosure is not limited thereto. The adhesive layer 260 is depicted as a single-layer structure in the drawings for the sake of simplicity and clarity.

Next, referring to FIG. 2F, the second substrate S2 is disposed on the adhesive layer 260, in accordance with some embodiments of the present disclosure. The second substrate S2 and the adhesive layer 260 are collectedly referred to as the connection assembly 250. The adhesive layer 260 is disposed between the support structure 230 and the second substrate S2. In some embodiments, the first substrate S1 and the second substrate S2 may include the same or different materials. The first substrate S1 and the second substrate S2 may include silicon, sapphire or other suitable material. According to some embodiments, the second substrate S2 may be adhered to the support structure 230 through the adhesive layer 260 to increase the bonding force between the second substrate S2 and the support structure 230.

Next, referring to FIG. 2G, the first substrate S1 is removed in accordance with some embodiments of the present disclosure. The first substrate S1 can be removed by stripping, etching, polishing, other suitable method, or a combination of the foregoing methods. In one embodiment, the first substrate S1 is de-attached from the first semiconductor layer 211 of the micro semiconductor device 200 through a laser lift off (LLO) method, so as to complete the removal of the first substrate S1.

As shown in FIG. 2G, in this embodiment, after the first substrate S1 is removed, the second surface 2002 (such as a light exist surface) of the micro semiconductor device 200 is exposed. The bottom surface 211b of the first semiconductor layer 211 is referred to as the second surface 2002 of the micro semiconductor device 200.

Next, referring to FIG. 2H, the first sacrificial layer 220 and the second sacrificial layer 240 are removed in accordance with some embodiments of the present disclosure. After the first sacrificial layer 220 is removed, the air gap 223 is formed at where the first sacrificial layer 220 was formed between the first electrode 217, between the second electrode 218 and between the support structure 230. In this embodiment, the air gap 223 includes air gap portions 224, 225 and 226. More specifically, the air gap portions 224 and 225 are formed between the first electrode 217 and the suspension portion 231 of the support structure 230, and the second electrode 218 and the suspension portion 231 of the support structure 230, respectively. The air gap portion 226 is formed around the periphery of the liner portion 232 of the support structure 230 (e.g., the periphery of the annular sidewall 2322).

As shown in FIG. 2H, after the second sacrificial layer 240 is removed, a void 243 is formed at the position which the second sacrificial layer 240 was formed, e.g., between the support structure 230 and the connection assembly 250. The void 243 includes the recess 230h (defined by the bottom portion 2321 and the annular wall 2322 of the liner portion 232) and an empty portion 245 above the recess 230h. In addition, the width of the empty portion 245 in the first direction DI is greater than the width of the recess 230h in the first direction D1. In addition, in some embodiments, the recess 230h is separated from the micro semiconductor device 200. Specifically, the recess 230h is positioned between the liner portion 232 and the connection assembly 250.

In addition, the first sacrificial layer 220 and the second sacrificial layer 240 can be removed by using any suitable method to form the air gap 223 and the void 243. For example, the first sacrificial layer 220 and the second sacrificial layer 240 may be removed by wet etching using one or more suitable chemical solutions. In addition, in some embodiments, the first sacrificial layer 220 and the second sacrificial layer 240 include the same material, and the first sacrificial layer 220 and the second sacrificial layer 240 can be removed simultaneously in one process (for example, the same wet etching process), thereby forming the foregoing air gap 223 and void 243.

In accordance with some embodiments of the present disclosure, the sacrificial layers (including the first sacrificial layer 220 and the second sacrificial layer 240) and the support structure 230 include different materials. Specifically, the support structure 230 is not substantially removed when the sacrificial layers are removed. In addition, when the sacrificial layers are removed, the other material layers would not be substantially removed or damaged. For example, the first semiconductor layer 211, the light-emitting layer 212, the second semiconductor layer 213, the first electrode 217, the second electrode 218 and the adhesive layer 260 are not removed or damaged when the sacrificial layers are removed. Therefore, in some embodiments, the chemical solvent that is used for removing the first sacrificial layer 220 and the second sacrificial layer 240 has high selectivity between the materials of the sacrificial layers and the materials of other above-mentioned structures/layers. Thus, after the first sacrificial layer 220 and the second sacrificial layer 240 are removed, the other structures/layers are substantially intact without being damaged.

Next, referring to FIG. 2I, the support structure 230 is broken off to form a semiconductor structure 300 having the support fragment SB in accordance with some embodiments of the present disclosure. The support structure 230 can be broken by pressing down, twisting, bending, other suitable method, or a combination of the foregoing methods. When the support structure 230 is broken, the portion of the support structure 230 remaining on the micro semiconductor device 200 may be retained or removed completely.

According to this embodiment, after a small external force is applied to the second substrate S2 (FIG. 2H) of the structure proposed in the embodiment to press the support structure 230 downwardly, the support structure 230 is easily disconnected at the part where the liner portion 232 is connected to the suspension portion 231. Alternately, the connection assembly 250 can be turned upside down, and the external force is applied to the epitaxial stack 210 to press the support structure 230 downwardly. As shown in FIG. 2I, after the support structure 230 is broken off, the liner portion 232 is left on the micro semiconductor component 200. For example, the liner portion 232 is left on the extension portion 217E of the first electrode 217. In some embodiments, the liner portion 232 remained on the micro semiconductor component 200 can also be referred to as the support fragment SB, and may remain on the micro semiconductor device 200 without being removed.

According to the semiconductor structure provided in the embodiments, the suspension portion 231 of the support structure 230 is supported by the liner portion 232 which has a relatively small area. A contact area between the suspension portion 231 and the liner portion 232 is very small so as to greatly reduce the external force required to break the support structure 230 and facilitate subsequent process to pick up the micro semiconductor device 200 by a pick-up device, even if the size of the micro semiconductor device 200 is further reduced. In addition, the air gap 223 between the suspension portion 231 and the electrodes (i.e., the first electrode 217 and the second electrode 218) and the void 243 between the support structure 230 and the connection assembly 250 provide the spaces for the support structure 230 to be pressed down. Thus, the support structure 230 of the embodiment has the benefit of being easily disconnected for later pick-up and transfer process. Specifically, the support structure 230 of the embodiments can be disposed within a vertical projection area of the first sacrificial layer 220, in other words, the support structure 230 overlaps with the micro semiconductor device 200 in the vertical direction (i.e., the third direction D3). Accordingly, the support structure 230 of the embodiments does not occupy additional space of the substrate, such as the lateral space of the substrate, thereby increasing the number of the semiconductor structures 300 that can be produced on a single wafer and avoiding wasting the wafer area.

According to some embodiments, a pick-up device is used to break the support structures 230 and place the semiconductor structures 300 with support fragments SB (FIG. 2I) on a transfer substrate (not shown). Next, these semiconductor structures 300 are electrically bonded to a carrier substrate (not shown) through the first electrodes 217 and the second electrodes 218. In some embodiments, the carrier substrate can be a rigid printed circuit board, a flexible printed circuit board, an aluminum substrate with high thermal conductivity, a ceramic substrate, a metal composite material substrate, a sapphire substrate, a glass substrate, or a semiconductor substrate with functional elements such as transistors or integrated circuits. In some embodiments, the carrier substrate can be a glass substrate with a thin-film transistor (TFT) or micro integrated circuits (micro IC).

In addition, in this embodiment, although a part of the support fragment SB protrudes from the first electrode 217 and the second electrode 218, the top surface 232a of the support fragment SB may be slightly higher than the top surface 217a of the first electrode 217 and the top surface 218a of the second electrode 218. When it is electrically bonded to the carrier (such as a printed circuit board) in a subsequent process, the bonding layer of the carrier also has an opening corresponding to the region between the first electrode 217 and the second electrode 218. In addition, the bonding layer of the carrier has a thickness. Therefore, the support fragment SB left on the micro semiconductor device 200 in accordance with some embodiments of the present disclosure does not affect the electrical connection between the first electrode 217, the second electrode 218 and the carrier (such as a printed circuit board) in a subsequent process.

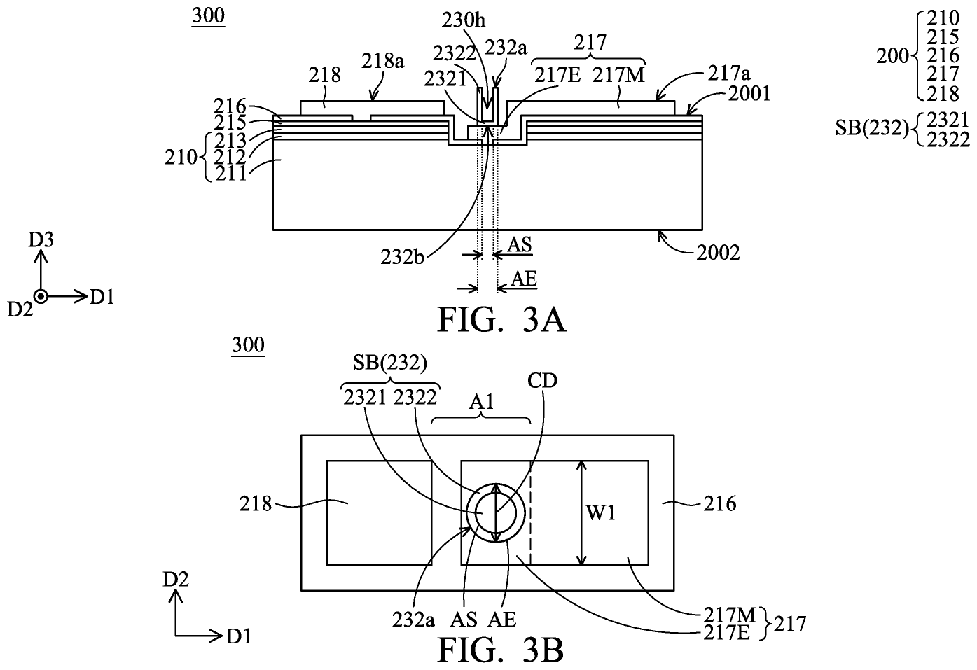

Referring to FIG. 3A and FIG. 3B. FIG. 3A is an enlarged view of a semiconductor structure 300 in accordance with some embodiments of the present disclosure. FIG. 3B is a schematic plan view of FIG. 3A. The features/components in FIG. 3A and FIG. 3B similar or identical to the features/components in FIG. 2A-FIG. 2I are designated with similar or the same reference numbers. The details of those similar or the identical features/components can be referred to the above-mentioned descriptions and are not repeated herein.

As shown in FIG. 3A, the semiconductor structure 300 includes the micro semiconductor device 200 and a support fragment SB. The micro semiconductor device 200 includes the first semiconductor layer 211, the light-emitting layer 212, the second semiconductor layer 213, the conductive layer 215, the passivation layer 216, the first electrode 217 and the second electrode 218. In some embodiments, after the support structure 230 is broken off, the liner portion 232 that remains on the micro semiconductor device 200 is referred to as the support fragment SB. The support fragment SB includes a bottom portion 2321 and an annular sidewall 2322 that is connected to the bottom portion 2321. In addition, in some embodiments, the bottom portion 2321 of the support fragment SB is disposed on the extension portion 217E of the first electrode 217.

In some embodiments, the support fragment SB has a U-shaped cross section. As shown in FIG. 3A, the support fragment SB can be a hollow cylinder with an opening (such as a recess 230h), and the opening faces away from the first surface 2001.

According to some embodiments, the support fragment SB has a top surface 232a and a bottom surface 232b opposite the top surface 232a, and the bottom surface 232b of the support fragment SB is disposed on the micro semiconductor device 200. As shown in FIG. 3B, the top surface 232a of the support fragment SB has an annular breaking surface when viewing from the top of the support fragment SB. In this embodiment, the aforementioned top surface 232a (having an annular area) is farther away from the micro semiconductor device 200 than the bottom surface 232b.

In addition, as shown in FIG. 3B, in some embodiments, the support fragment SB is arranged within the region A1 between the main portion 217M of the first electrode 217 and the second electrode 218. More specifically, the first electrode 217 and the second electrode 218 are separated from each other in the first direction D1, and the region A1 between the main portion 217M of the first electrode 217 and the second electrode 218 includes the extending portion 217E of the first electrode 217 connected to the main portion 217M of the first electrode 217, and the support fragment SB is connected to the extending portion 217E and arranged within the area of the same. Moreover, the support fragment SB has a critical dimension CD in the second direction D2, the electrode connected with the support fragment SB, i.e., the first electrode 217 in this embodiment, has an electrode width W1 in the second direction D2. The critical dimension CD is less than the electrode width W1.

In addition, in some embodiments, in the semiconductor structure 300 as shown in FIG. 3A and FIG. 3B, the top surface 232a of the support fragment SB may have an annular area as shown in FIG. 3B and have a vertical projection on the second surface 2002 of the micro semiconductor device 200 including an outer-diameter range AE and an inner-diameter range AS (i.e., AE>AS). In some embodiments, when the annular area of the top surface 232a of the support fragment SB is greater than 10% of a total area of the micro semiconductor device 200, the micro semiconductor device 200 can be firmly supported by the support structure 230 after the first sacrificial layer 220 and the second sacrificial layer 240 are removed, but, at the same time, the support structure 230 is hard to break and the pick-up rate of the subsequent pick-up process can be decreased. When the annular area of the top surface 232a of the support fragment SB is less than 0.1% of a total area of the micro semiconductor device 200, the micro semiconductor device 200 may fall down due to the insufficient support force of the support structure 230 after the first sacrificial layer 220 and the second sacrificial layer 240 are removed, and abnormal phenomenon of chip missing or chip defects can occur. In some embodiments, the production yield is better when the ratio of the annular area of the top surface 232a of the support fragment SB to the total area of the micro semiconductor device 200 is between 0.1% and 10%. In some embodiments, the size of the micro semiconductor device 200 is 40 μm×20 μm, the diameter of AE (i.e., the outer-diameter range of the top surface 232a of the support fragment SB on the second surface 2002) is 8 μm, the diameter of AS (i.e., the inner-diameter range of top surface 232a of the support fragment SB on the second surface 2002) is 4 μm, the annular wall thickness, i.e., half of the diameter difference between the outer diameter and the inner diameter, of the top surface 232a of the support fragment SB is 2 μm, and the annular area of the top surface 232a of the support fragment SB is about 4.7% of the total area of the micro semiconductor device 200. In some other embodiments, the size of the micro semiconductor device 200 is 100 μm×50 μm, the diameter of AE is 5 μm, the diameter of AS is 3 μm, the annular wall thickness of the top surface 232a of the support fragment SB is 1 μm, and the annular area of the top surface 232a of the support fragment SB is about 0.3% of the total area of the micro semiconductor device 200.

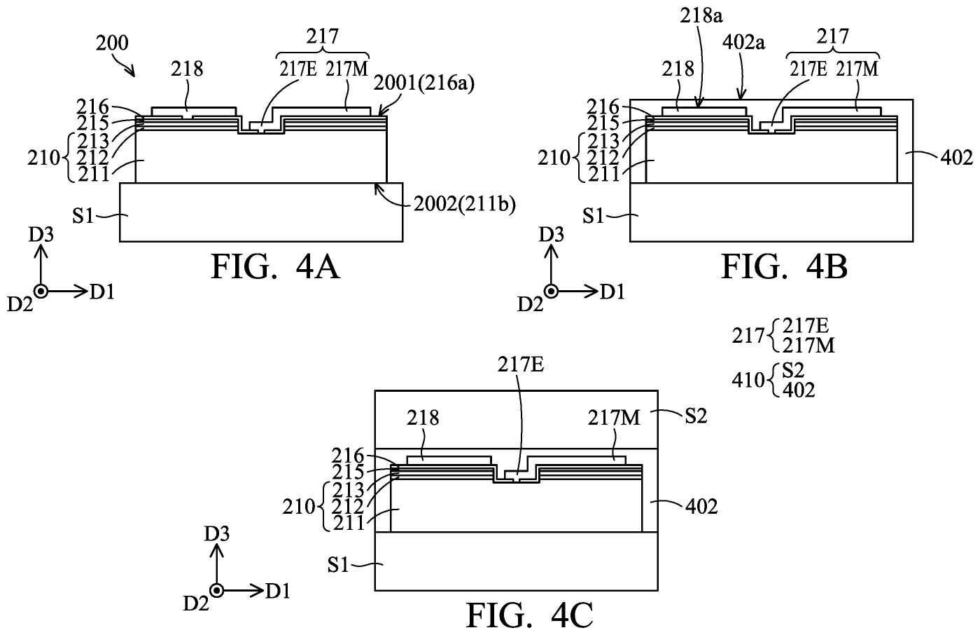

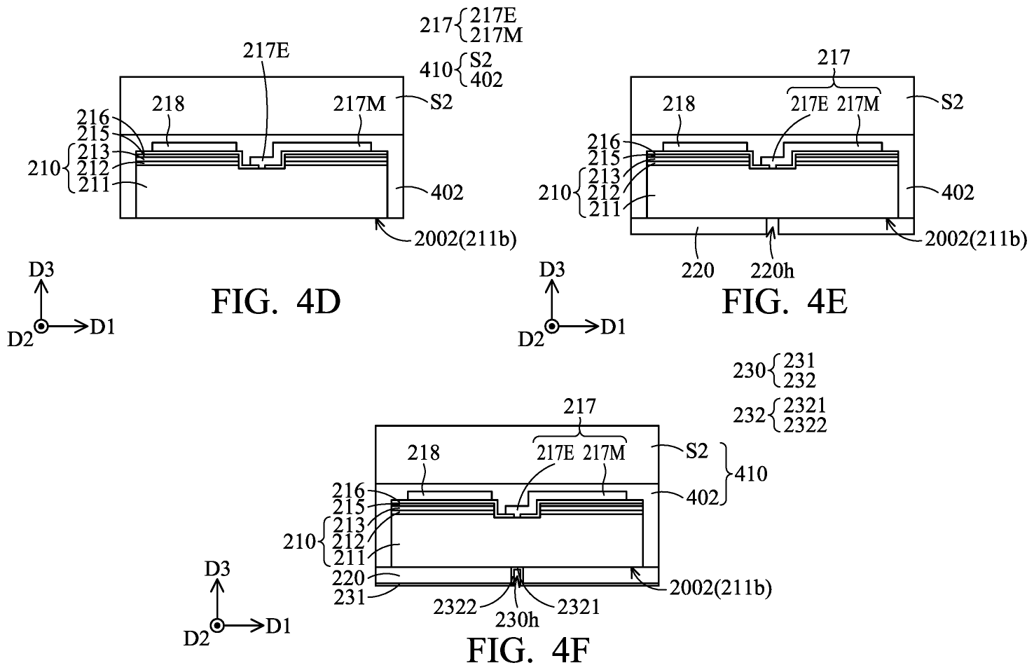

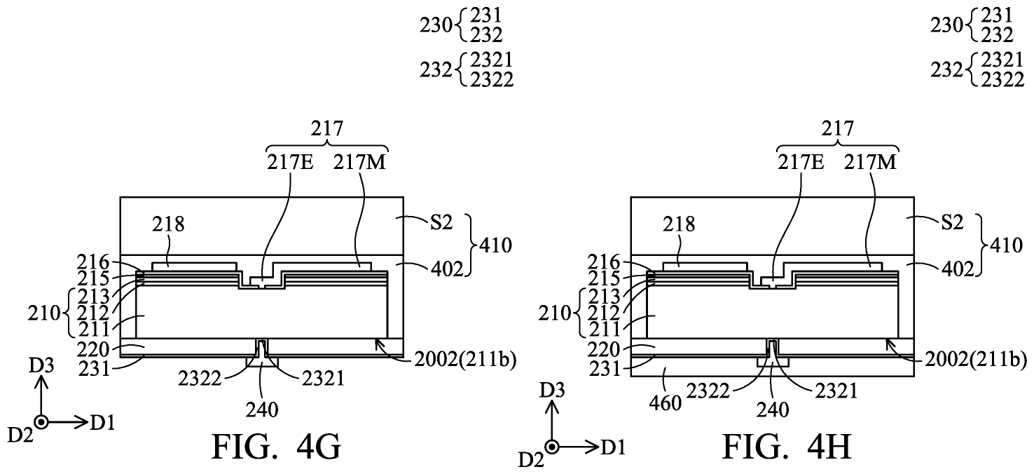

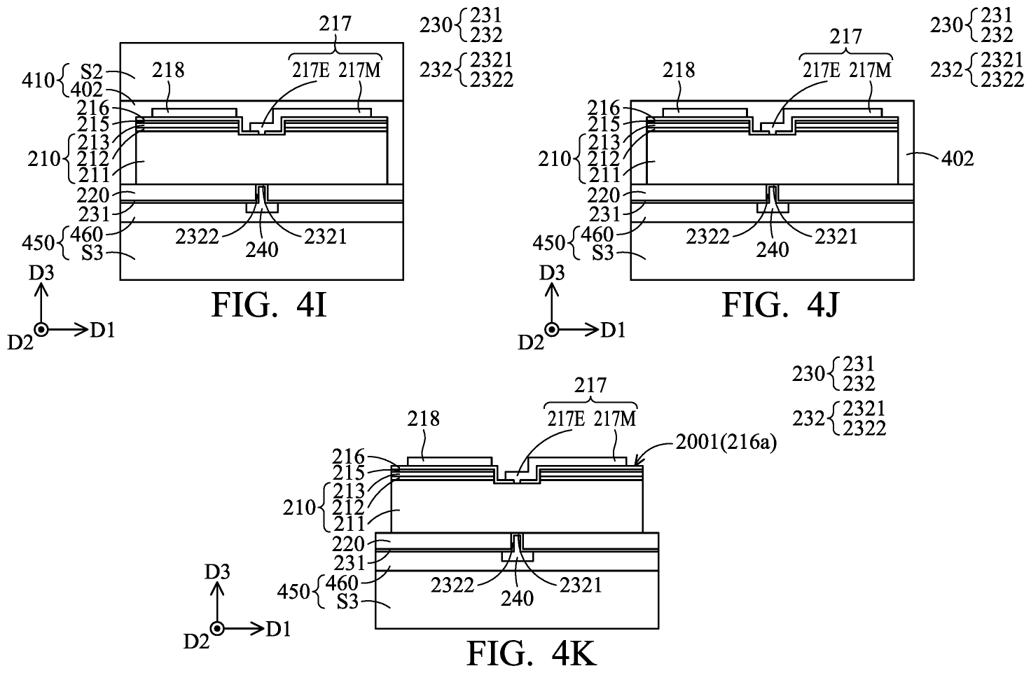

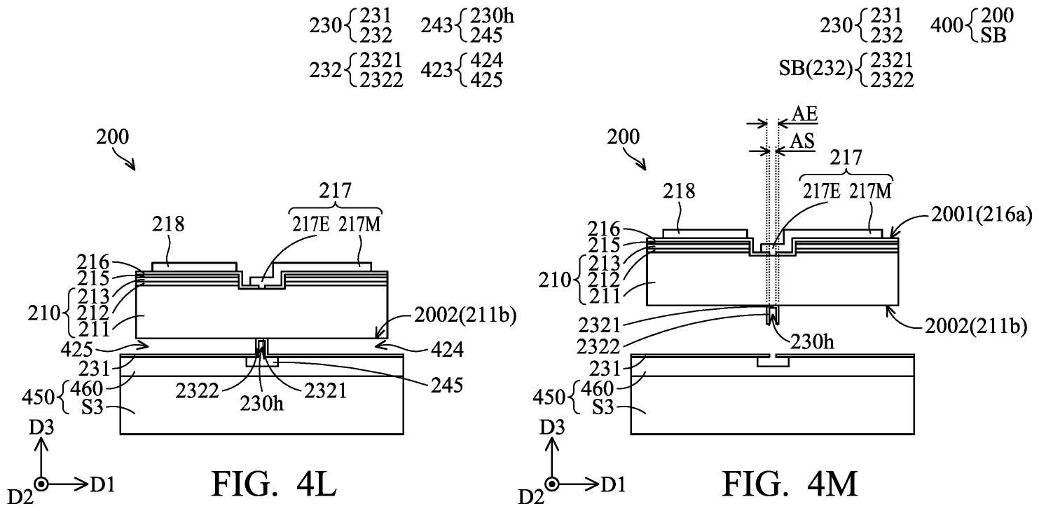

In addition to the above-mentioned manufacturing method as proposed in FIG. 2A-FIG. 2I, other suitable manufacturing method can also be used to obtain the semiconductor structure containing the support fragment. FIG. 4A-FIG. 4M illustrate cross-sectional views of different stages of forming another semiconductor structure having a support fragment in accordance with some embodiments of the present disclosure.

The features/elements in FIG. 4A-FIG. 4M that are similar or identical to the features/elements in FIG. 2A-FIG. 2I are designated with similar or the same reference numbers, and the details of those similar or the identical features/elements are similar to the related contents in the aforementioned descriptions. Different from the support fragment SB formed by the method in FIG. 2A-FIG. 2I, which the support fragment SB is disposed on the first surface 2001 of the micro semiconductor device 200, the support fragment SB formed by the method in FIG. 4A-FIG. 4M is disposed on the second surface 2002 (such as the light exist surface) of the micro semiconductor device 200.

Referring to FIG. 4A, a micro semiconductor device 200 (such as a micro-light-emitting diode) is formed on the first substrate S1 in accordance with some embodiments of the present disclosure. The first substrate S1 includes silicon, sapphire, or other suitable materials. The micro semiconductor device 200 includes a first semiconductor layer 211, a light-emitting layer 212, a second semiconductor layer 213, a conductive layer 215, a passivation layer 216, a first electrode 217 and a second electrode 218. The first electrode 217 is electrically connected to the first semiconductor layer 211. The second electrode 218 is electrically connected to the conductive layer 215 and the second semiconductor layer 213. In some embodiments, the micro semiconductor device 200 has a first surface 2001 and a second surface 2002 opposite the first surface 2001. As shown in FIG. 4A, the top surface 216a of the passivation layer 216 is also referred to as the first surface 2001, and the bottom surface 211b of the first semiconductor layer 211 is also referred to as the second surface 2002. In addition, the second surface 2002 is a light exist surface of the micro semiconductor device 200. In this embodiment, the first electrode 217 and the second electrode 218 are disposed on the first surface 2001 and separated from each other by a distance. Details of the arrangement, materials and manufacturing methods of the components in FIG. 4A can be referred to the above-mentioned descriptions in FIG. 2A, and are not repeated herein.

Next, a first connection assembly 410 is formed on the first substrate S1 and the micro semiconductor device 200, as shown in FIG. 4B and FIG. 4C. The first connection assembly 410 includes a first adhesive layer 402 and second substrate S2.

Referring to FIG. 4B, a first adhesive layer 402 is formed on the first substrate S1 and the micro semiconductor device 200 in accordance with some embodiments of the present disclosure. The thickness of the first adhesive layer 402 is sufficient to cover the micro semiconductor device 200. For example, the first adhesive layer 402 covers the sidewalls of the first semiconductor layer 211, the light-emitting layer 212, the second semiconductor layer 213, the conductive layer 215 and the passivation layer 216. The first adhesive layer 402 also covers the sidewalls and top surfaces of the first electrode 217 and the second electrode 218. The first adhesive layer 402 also covers the exposed portion of the top surface of the passivation layer 216. As shown in FIG. 4B, the top surface 402a of the first adhesive layer 402 is higher than the top surface 217a of the first electrode 217 and the top surface 218a of the second electrode 218.

Details of the material and manufacturing method of the first adhesive layer 402 in FIG. 4B can be referred to the above-mentioned descriptions of the adhesive layer 260 in FIG. 2E and are not repeated herein. In addition, the first adhesive layer 402 can be a single-layer structure or a multilayer structure. In this embodiment, the first adhesive layer 402 is depicted as a single-layer structure for the purpose of simplicity and clarity of the drawings, but the disclosure is not limited thereto.

Next, referring to FIG. 4C, the second substrate S2 is disposed on the first adhesive layer 402 in accordance with some embodiments of the present disclosure. The second substrate S2 and the first adhesive layer 402 are collectedly referred to as the first connection component 410. The second substrate S2 is not in direct contact with the first electrode 217 and the second electrode 218 by disposing the first adhesive layer 402. The second substrate S2 may include silicon, sapphire or other suitable materials. In some embodiments, the first substrate S1 and the second substrate S2 include the same material.

Next, referring to FIG. 4D, the first substrate S1 is removed in accordance with some embodiments of the present disclosure. The first substrate S1 can be removed by stripping, etching, polishing, other suitable methods, or a combination of the foregoing methods. In one embodiment, the first substrate S1 is removed from the first semiconductor layer 211 of the micro semiconductor device 200 through a laser lift off (LLO) method.

As shown in FIG. 4D, in this embodiment, after the first substrate S1 is removed, the second surface 2002 (such as the light exist surface) of the micro-semiconductor device 200 is exposed. That is, the bottom surface 211b of the first semiconductor layer 211 is exposed.

Next, referring to FIG. 4E, in some embodiments, a first sacrificial layer 220 is formed on the micro semiconductor device 200 in FIG. 4A. Specifically, the first sacrificial layer 220 is formed on the side of the second surface 2002 of the micro semiconductor device 200 and covers the micro semiconductor device 200 and the first adhesive layer 402. The first sacrificial layer 220 has a hole 220h that exposes the second surface 2002. In addition, in this embodiment, the hole 220h of the first sacrificial layer 220 corresponds to the space between the main portion 217M of the first electrode 217 and the second electrode 218 in the third direction D3. After the subsequent processes is completed and the support structure 230 is broken off, the remaining portion, which is referred to as the support fragment SB, corresponds to the position of the hole 220h.

Next, referring to FIG. 4F, a support structure 230 is conformally formed on the first sacrificial layer 220 in accordance with some embodiments of the disclosure. The support structure 230 includes a suspension portion 231 and a liner portion 232. The material layer is conformally deposited in the hole 220h of the first sacrificial layer 220 to form the liner portion 232 and define a recess 230h.

In some embodiments, the liner portion 232 includes a bottom portion 2321 and an annular sidewall 2322. The bottom portion 2321 is connected to the micro-semiconductor device 200, for example, be in contact with the portion of the second surface 2002 exposed from the hole 220h. The annular sidewall 2322 is connected to the bottom portion 2321. The bottom portion 2321 and the annular sidewall 2322 collectively define the recess 230h.

In addition, in some embodiments, the suspension portion 231 is connected to the annular sidewall 2322 of the liner portion 232 and the suspension portion 231 extends along the second direction D2 to cover the first sacrificial layer 220. It should be noted that the suspension portion 231 is not in direct contact with the second surface 2002 of the micro semiconductor device 200. As shown in FIG. 4F, the suspension portion 231 is separated from the first second surface 2002 of the micro semiconductor device 200 (in the third direction D3) by the first sacrificial layer 220.

In addition, in this embodiment, since the support structure 230 is positioned on the second surface 2002 (which is the light exist surface) of the micro semiconductor device 200, it is better to have the support structure 230 with high light transmittance, e.g., at least 80% for the light emits from the micro semiconductor device 200. In some embodiments, the light transmittance of the support structure 230 may be equal to or greater than 80%, equal to or greater than 85%, equal to or greater than 90% or equal to or greater than 95%. In some embodiments, the support structure 230 includes, for example, silicon oxide, silicon nitride, silicon oxynitride, epoxy resin, or other suitable materials, but the present disclosure is not limited thereto. In addition, the support structure 230 may be a single-layer structure or a multi-layer structure. The support structure 230 is depicted as a single-layer structure in the drawings for the sake of simplicity and clarity.

Next, referring to FIG. 4G, a second sacrificial layer 240 is formed at the recess 230h in accordance with some embodiments of the present disclosure. Specifically, the second sacrificial layer 240 is formed on a portion of the support structure 230. As shown in FIG. 4G, the second sacrificial layer 240 is formed in the recess 230h to cover the liner portion 232 of the support structure 230. Moreover, the second sacrificial layer 240 extends from the recess 230h to the outside of the recess 230h and covers a portion of the suspension portion 231. In some embodiments, the second sacrificial layer 240 protrudes from the suspension portion 231 of the support structure 230.

Next, a connection assembly 450 is formed on the support structure 230 and the second sacrificial layer 240. As shown in FIG. 4H and FIG. 4I, the connection assembly 450 includes a second adhesive layer 460 and a third substrate S3.

Referring to FIG. 4H, the second adhesive layer 460 is formed to cover the support structure 230 and the second sacrificial layer 240 in accordance with some embodiments of the present disclosure. In other words, the second sacrificial layer 240 is arranged between the support structure 230 and the second adhesive layer 460. The thickness of the second adhesive layer 460 is sufficient to cover the support structure 230 (e.g., the suspension portion 231) and the second sacrificial layer 240.

Details of the material and manufacturing method of the second adhesive layer 460 in FIG. 4H can be referred to the above-mentioned descriptions of the adhesive layer 260 in FIG. 2E and are not repeated herein. In addition, the second adhesive layer 460 can be a single-layer structure or a multilayer structure. In this embodiment, the second adhesive layer 460 is depicted as a single-layer structure for the purpose of simplicity and clarity of the drawings. However, the present disclosure is not limited thereto. In addition, the second adhesive layer 460 and the first adhesive layer 402 may include the same material or different materials.

Next, referring to FIG. 4I, the third substrate S3 is disposed to cover the second adhesive layer 460 in accordance with some embodiments of the present disclosure. In other words, the second adhesive layer 460 is disposed between the support structure 230 and the third substrate S3. The third substrate S3 and the second adhesive layer 460 are collectedly referred to as the second connection assembly 450. The third substrate S3 may include silicon, sapphire or other suitable materials. However, the present disclosure is not limited thereto. The first substrate S1, the second substrate S2 and the third substrate S3 may include the same or different materials. In some embodiments, the third substrate S3 can be adhered to the support structure 230 through the second adhesive layer 460 to increase the bonding force between the third substrate S3 and the support structure 230.

Next, referring to FIG. 4J, the second substrate S2 is removed in accordance with some embodiments of the present disclosure. The second substrate S2 can be removed by stripping, etching, polishing, other suitable methods, or a combination of the foregoing methods. In one embodiment, the second substrate S2 is removed from the first adhesive layer 402 through a laser lift off (LLO) method, so as to complete the removal of the second substrate S2. It should be noted that the first adhesive layer 402 still covers the micro semiconductor device 200 after the second substrate S2 is removed.

Next, referring to FIG. 4K, the first adhesive layer 402 is removed in accordance with some embodiments of the present disclosure. After the first adhesive layer 402 is removed, the micro semiconductor device 200 is exposed. For example, the first surface 2001, the first electrode 217 and the second electrode 218 are exposed, but the removal of the first adhesive layer 402 does not cause substantial damage to the second adhesive layer 460. Therefore, there is good bonding force between the third substrate S3 and the support structure 230 through the second adhesive layer 460.

Next, referring to FIG. 4L, the first sacrificial layer 220 and the second sacrificial layer 240 are removed in accordance with some embodiments of the present disclosure. After the first sacrificial layer 220 is removed, the air gap 423 is formed at where the first sacrificial layer 220 was formed between the second surface 2002 of the micro semiconductor device 200 and the support structure 230. In this embodiment, the air gap 423 includes air gap portions 424 and 425. More specifically, the air gap portion 424 and the air gap portion 425 are formed between the second surface 2002 and the suspension portion 231 of the support structure 230 and respectively corresponding to the first electrode 217 and the second electrode 218 in the third direction D3.

As shown in FIG. 4L, after the second sacrificial layer 240 is removed, a void 243 is formed at the position the second sacrificial layer 240 was formed. The void 243 includes the recess 230h (defined by the bottom portion 2321 and the annular sidewall 2322) and an empty portion 245 connected to the recess 230h. In addition, in some embodiments, the recess 230h is separated from the micro semiconductor device 200. The recess 230h is positioned between the liner portion 231 and the second connection assembly 450. Details of the method of forming the air gap 423 can be referred to the above-mentioned descriptions of the air gap 223, and are not repeated herein.

In addition, the sacrificial layers (including the first sacrificial layer 220 and the second sacrificial layer 240) and the support structure 230 include different materials, in accordance with some embodiments of the present disclosure. The support structure 230 is not substantially removed when the sacrificial layers are removed. In addition, when the sacrificial layers are removed, the other material layers would not be substantially removed or damaged. For example, the first semiconductor layer 211, the light-emitting layer 212, the second semiconductor layer 213, the first electrode 217, the second electrode 218 and the second adhesive layer 460 of the micro semiconductor device 200 are not removed or damaged when the sacrificial layers are removed. Therefore, in some embodiments, the chemical solvent that is used for removing the first sacrificial layer 220 and the second sacrificial layer 240 has high selectivity between the materials of the sacrificial layers and the materials of the above-mentioned other structures/layers. Thus, after the first sacrificial layer 220 and the second sacrificial layer 240 are removed, the other structures/layers are substantially intact without being damaged.

Next, referring to FIG. 4M, the support structure 230 is broken off to form a semiconductor structure 400 having support fragment SB in accordance with some embodiments of the present disclosure. The support structure 230 can be broken by pressing down, twisting, bending, other suitable methods, or a combination of the foregoing methods. When the support structure 230 is broken off, the portion of the support structure 230 remaining on the micro semiconductor device 200 may be retained or removed completely.

According to this embodiment, since the void 243 formed between the support structure 230 and the second connection assembly 450, the micro semiconductor device 200 is supported by a hollow cylinder (i.e., 231 the liner portion 232) which can be broken off by a relatively small force comparing to a solid cylinder. When a small external force is applied to the micro semiconductor device 200 to press the support structure 230 downwardly, the support structure 230 is easily broken at the part where the liner portion 232 is connected to the suspension portion 231. As shown in FIG. 4M, after the support structure 230 is broken, the liner portion 232 is left on the micro semiconductor device 200 and can also be referred to as support fragment SB. The support fragment SB may remain on the micro semiconductor device 200 without being removed. The difference between FIG. 2I and FIG. 4M is that the support fragment SB in FIG. 2I is located at the extension portion 217E of the first electrode 217, i.e., the non-light exist surface of the micro semiconductor device 200, and the support fragment SB in FIG. 4M is located at the second surface 2002, i.e., the light exist surface of the micro semiconductor device 200. As shown in FIG. 4M, the support fragment SB is in direct contact with the second surface 2002. In addition, in some embodiments, the support fragment SB has a configuration of a hollow cylinder with an opening (such as the recess 230h), and the opening faces away from the second surface 2002.

In addition, similar to the support fragments SB in the examples of FIG. 2I and FIG. 3A, the top surface of the support fragment SB has an annular breaking surface in a plan view of the semiconductor structure 400 (FIG. 4M). In addition, according to the support fragment SB in this embodiment, the outer-diameter range AE of the annular sidewall 2322 on the second surface 2002 of the micro semiconductor device 200 encompasses the inner-diameter range AS of the annular sidewall 2322 on the second surface 2002 of the micro semiconductor device 200 (i.e., AE>AS).

The disclosed semiconductor structures and the methods of forming the same can be not only used in the light emitting diodes (LEDs) and micro-light-emitting diodes (micro-LEDs) whose sizes are down to micron (μm) level, but also widely used in the displays and wearable devices. Those LEDs can be red, green or blue LEDs.

According to the aforementioned descriptions, the semiconductor structures and the methods of forming the same in accordance with some embodiments of the present disclosure have many advantages. The support fragment may be formed over the first surface or the opposite second surface of the micro semiconductor device. For example, the support fragment may be arranged so that it corresponds to the region between the main portion of the first electrode and the second electrode of the micro semiconductor device, so it does not occupy additional lateral space over the substrate, thereby increasing the quantity of micro semiconductor devices that can be produced on a single wafer. In addition, in the methods of forming semiconductor structures proposed in the above-mentioned embodiments, the support structure 230 not only has the benefits of the anchor-type weakened structure such as providing stable support without taking lateral space of the wafer, but also has the benefits of easy disconnection of the tether-type weakened structure. In addition, the methods of forming the semiconductor structure in accordance with some embodiments are simple and compatible with the existing semiconductor manufacturing process. Thus, the embodied methods are suitable for mass production, and can be applied to fabricate the support structures with high precision using suitable photolithography process.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor structure, comprising:
a micro semiconductor device having a first surface, a second surface opposite the first surface, a first electrode on the first surface, and a second electrode on the first surface, wherein the first electrode and the second electrode are separated from each other, and the first electrode has a main portion; and
a support fragment connected to the micro semiconductor device, the support fragment is arranged corresponding to a region between the main portion of the first electrode and the second electrode in a vertical direction,
wherein the support fragment has an annular breaking surface in a plan view of the support fragment.

2. The semiconductor structure as claimed in claim 1, wherein the support fragment has a U-shaped cross section.

3. The semiconductor structure as claimed in claim 1, wherein the support fragment includes a bottom portion contacted to the micro semiconductor device and an annular sidewall connected to the bottom portion.

4. The semiconductor structure as claimed in claim 1, wherein the support fragment is a hollow cylinder having an opening, and the opening faces away from the micro semiconductor device.

5. The semiconductor structure as claimed in claim 1, wherein the support fragment has a bottom surface opposite to the annular breaking surface, the bottom surface is closer to the micro semiconductor device than the annular breaking surface, wherein a ratio of a plan view area of the annular breaking surface to a plan view area of the micro semiconductor device is in a range of 0.1% to 10%.

6. The semiconductor structure as claimed in claim 5, wherein the first electrode includes an extension portion that is connected to the main portion, and the bottom surface of the support fragment is disposed on the extension portion of the first electrode.

7. The semiconductor structure as claimed in claim 5, wherein the support fragment is disposed on the second surface of the micro semiconductor device, and the bottom surface of the support fragment is in direct contact with the second surface.

8. The semiconductor structure as claimed in claim 1, wherein the first electrode has an extension portion that is connected to the main portion and extends toward the second electrode, and a vertical projection of the support fragment on the second surface of the micro semiconductor device is within a vertical projection of the extension portion of the first electrode on the second surface of the micro semiconductor device.

9. A method of forming a semiconductor structure, comprising:
providing a micro semiconductor device having a first surface, a second surface opposite the first surface, a first electrode on the firs surface, and a second electrode on the first surface, wherein the first electrode and the second electrode are separated from each other, and the first electrode has a main portion; and
forming a support fragment connected to the micro semiconductor device, and the support fragment is arranged corresponding to a region between the main portion of the first electrode and the second electrode in a vertical direction, wherein the support fragment has an annular breaking surface in a plan view of the support fragment.

10. The method of forming a semiconductor structure as claimed in claim 9, wherein the first electrode includes an extension portion that is connected to the main portion, and a vertical projection of the support fragment on the second surface of the micro semiconductor device is within a vertical projection of the extension portion of the first electrode on the second surface of the micro semiconductor device.

11. The method of forming a semiconductor structure as claimed in claim 10, wherein forming the support fragment comprises:
forming a first sacrificial layer on the first surface of the micro semiconductor device, wherein the first sacrificial layer covers the first electrode and the second electrode, the first sacrificial layer has a hole that is located between the first electrode and the second electrode, and the hole exposes a portion of the first electrode;
conformally forming a support structure on the first sacrificial layer, the support structure covers the first sacrificial layer and extends into the hole to cover the portion of the first electrode which the hole exposes, wherein the support structure has a recess corresponding to the hole of the first sacrificial layer;
forming a second sacrificial layer at the recess;
forming a connection assembly over the support structure and the second sacrificial layer;
removing the first sacrificial layer and the second sacrificial layer; and
breaking the support structure to remove the connection assembly.

12. The method of forming a semiconductor structure according to claim 11, wherein the support structure comprises a suspension portion and a liner portion connected to the suspension portion, the suspension portion covers the first sacrificial layer outside of the hole, and the liner portion covers the first sacrificial layer in the hole and the portion of the first electrode which the hole exposes.

13. The method of forming a semiconductor structure according to claim 12, wherein the liner portion comprises a bottom portion connected to the micro semiconductor device and an annular sidewall connected to the bottom portion, and the suspension portion is connected to the annular sidewall.

14. The method of forming a semiconductor structure according to claim 11, wherein after the first sacrificial layer and the second sacrificial layer are removed, an air gap is formed between the micro semiconductor device and the suspension portion of the support structure.

15. The method of forming a semiconductor structure according to claim 11, wherein after the first sacrificial layer and the second sacrificial layer are removed, a void is formed between the support structure and the connection assembly.

16. The method of forming a semiconductor structure according to claim 11, wherein the micro semiconductor device is provided on a first substrate, and after the second sacrificial layer is formed and before the first sacrificial layer and the second sacrificial layer are removed, the method further comprises:
forming an adhesive layer to cover the support structure and the second sacrificial layer;
disposing a second substrate on the adhesive layer, wherein the second substrate and the adhesive layer constitute the connection assembly; and
removing the first substrate.

17. The method of forming a semiconductor structure according to claim 10, wherein forming the support fragment comprises:
forming a first connection assembly above the first surface of the micro semiconductor device, wherein the first connection assembly covers the first electrode and the second electrode;
forming a first sacrificial layer on the second surface of the micro semiconductor device, wherein the first sacrificial layer has a hole corresponding to the region between the main portion of the first electrode and the second electrode in the vertical direction, and the hole exposes a portion of the second surface;
conformally forming a support structure on the first sacrificial layer, the support structure covers the first sacrificial layer and extends into the hole to cover the portion of the second surface which the hole exposes, wherein the support structure has a recess corresponding to the hole of the first sacrificial layer;
forming a second sacrificial layer at the recess;
forming a second connection assembly over the support structure and the second sacrificial layer;
removing the first connection assembly;
removing the first sacrificial layer and the second sacrificial layer; and
removing the second connection assembly by breaking the support structure.

18. The method of forming a semiconductor structure as claimed in claim 17, wherein after the first sacrificial layer and the second sacrificial layer are removed, an air gap is formed between the second surface of the micro semiconductor device and the suspension portion of the support structure.

19. The method of forming a semiconductor structure as claimed in claim 17, wherein after the first sacrificial layer and the second sacrificial layer are removed, a void is formed between the support structure and the second connection assembly.

20. The method of forming a semiconductor structure as claimed in claim 17, wherein the micro semiconductor device is disposed on a first substrate, and forming the first connection assembly further comprises:
forming a first adhesive layer on the first surface of the micro semiconductor device, wherein the first adhesive layer covers the first electrode and the second electrode; and
disposing a second substrate over the first adhesive layer,
wherein forming the second connection assembly further comprises:
forming a second adhesive layer to cover the support structure and the second sacrificial layer; and
disposing a third substrate over the second adhesive layer.

21. The method of forming a semiconductor structure as claimed in claim 20, wherein after the first connection assembly is formed, the first substrate is removed to expose the second surface of the micro semiconductor device; and
after the second connection assembly is formed, the second substrate and the first adhesive layer of the first connection assembly are sequentially removed to expose the first surface of the micro semiconductor device, the first electrode and the second electrode.
